(19) United States
(12) Patent Application Publication
(10) Pub. No.: US 2026/0107825 A1
(43) Pub. Date: Apr. 16, 2026

(54) MOLD COMPOUND VOID MITIGATION

(71) Applicant: TEXAS INSTRUMENTS INCORPORATED, Dallas, TX (US)

(72) Inventors: Ter Wee LEE, Melaka (MY); Yien Sien KHOO, Alor Gajah (MY)

(21) Appl. No.: 18/917,720

(22) Filed: Oct. 16, 2024

(51) Int. Cl. H01L 23/31; H01L 21/56

(52) U.S. Cl. CPC H10W 74/124; H10W 74/016

(57) ABSTRACT

In examples, a semiconductor package comprises a semiconductor die, a conductive terminal coupled to the semiconductor die, and a mold compound covering the semiconductor die and the conductive terminal. The mold compound has first and second portions, with the first portion being thicker than the second portion. The second portion extends along an edge of the mold compound and includes a cavity. The cavity has a floor and an elevated member on the floor, the elevated member extending lengthwise from a lateral surface of the first portion toward the second portion such that a line extending axially through the elevated member intersects a plane in which the lateral surface lies.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing the integrated circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a semiconductor die, a conductive terminal coupled to the semiconductor die, and a mold compound covering the semiconductor die and the conductive terminal. The mold compound has first and second portions, with the first portion being thicker than the second portion. The second portion extends along an edge of the mold compound and includes a cavity. The cavity has a floor and an elevated member on the floor, the elevated member extending lengthwise from a lateral surface of the first portion toward the second portion such that a line extending axially through the elevated member intersects a plane in which the lateral surface lies.

In examples, a method for manufacturing a semiconductor package comprises coupling a semiconductor die to a lead frame; positioning the lead frame in a mold chase; and lowering a mold chase platen of the mold chase over the lead frame such that a pillar of the mold chase platen contacts the lead frame, the pillar having first and second prongs and a channel extending lengthwise between the first and second prongs. The method also includes injecting a mold compound into the mold chase such that the mold compound flows through the channel between the first and second prongs and curing the mold compound. The method comprises sawing through the cured mold compound to produce the semiconductor package, the semiconductor package including first and second portions of the mold compound, the first portion thicker than the second portion, the second portion extending along an edge of the mold compound and including a cavity, the cavity having a floor and an elevated member on the floor, the elevated member formed by the mold compound flowing through the channel, the elevated member extending lengthwise from a lateral surface of the first portion toward the second portion such that a line extending axially through the elevated member is perpendicular to a vertical plane in which the lateral surface lies.

### BRIEF DESCRIPTION OF THE DRAWINGS

FIGS. 1A-1E are perspective, top-down, profile, profile, and bottom-up views, respectively, of a semiconductor package manufactured according to a mold compound void mitigation process, in accordance with various examples.

FIGS. 2A-2M5 depict a semiconductor package manufacturing process that mitigates the formation of mold compound voids, in accordance with various examples.

FIG. 3 is a flow diagram of a semiconductor package manufacturing process that mitigates the formation of mold compound voids, in accordance with various examples.

FIG. 4 is a block diagram of an electronic device including a semiconductor package manufactured according to a mold compound void mitigation process, in accordance with various examples.

### DETAILED DESCRIPTION

The semiconductor package manufacturing process entails placing lead frames and semiconductor dies in mold chases, which are specialized cavities designed to shape a mold compound around the components. The mold chase platen (e.g., mold chase top lid) features pillars that provide mechanical support to the lead frame during injection of the mold compound into the mold chase, ensuring the various structures remain in position. However, as the mold compound is injected and flows around these support pillars, voids—small pockets of trapped air—can form within the mold compound. These voids are detrimental because they create weak points within the encapsulated material. Voids can compromise the mechanical integrity of the package, leading to potential cracks, especially under thermal stress or mechanical loading. Additionally, voids can allow moisture to penetrate the package, leading to corrosion of the internal components or delamination of the mold compound from the lead frame or die surface. This can ultimately result in device failure, reducing the reliability and lifespan of the semiconductor package.

Additionally, when it comes to singulating the mold-covered lead frames and dies into individual packages, the thickness of the mold compound can introduce several technical challenges. Thick mold compounds require a slower saw feed speed to ensure precise cuts without damaging the components, which in turn increases the overall manufacturing time. Moreover, the increased thickness adds more material for the saw blade to cut through, leading to greater wear and tear on the blade. This not only necessitates more frequent blade replacements but also increases manufacturing costs. Furthermore, thick mold compounds contribute to the bulk of the final semiconductor package, which can be a disadvantage in applications where space is at a premium, such as in mobile devices or other compact electronics. Excessive mold compound thickness can also lead to increased manufacturing inefficiencies and costs.

This disclosure describes various examples of a manufacturing technique for mitigating the presence of voids in semiconductor package mold compounds, thereby mitigating the technical challenges associated with mold compound voids, such as those described above. The manufacturing technique also strategically reduces mold compound thickness, thereby leading to decreasing manufacturing time and inefficiency, decreased manufacturing costs, reduced semiconductor package bulk, and reduced blade wear and tear. The manufacturing technique described herein includes positioning a lead frame, which has semiconductor dies coupled thereto, in a mold chase that includes a mold chase platen with pillars shaped to facilitate mold compound flow without void formation. The mold chase platen has a convex shape that reduces mold compound thickness and bulk, resulting in the numerous technical advantages described above. An example semiconductor package may include a semiconductor die, a conductive terminal coupled to the semiconductor die, and a mold compound covering the semiconductor die and the conductive terminal. The mold compound may have first and second portions, where the first portion is thicker than the second portion, and the second portion extends along an edge of the mold compound and includes a cavity. The cavity has a floor and an elevated member on the floor. The elevated member extends lengthwise from a lateral surface of the first portion toward the second portion such that a line extending axially through the elevated member is perpendicular to a plane in which the lateral surface lies.

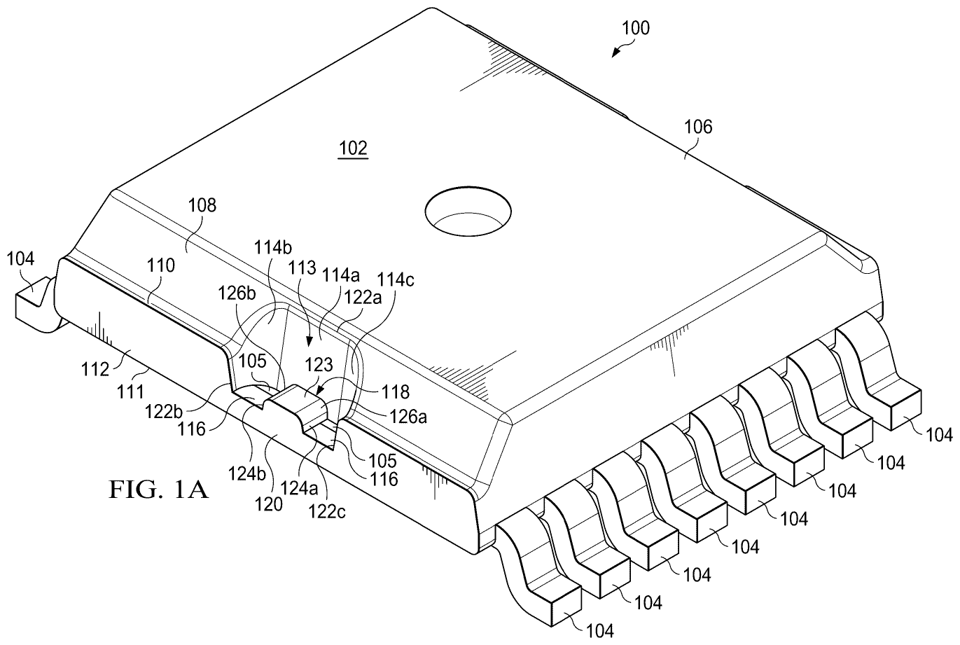

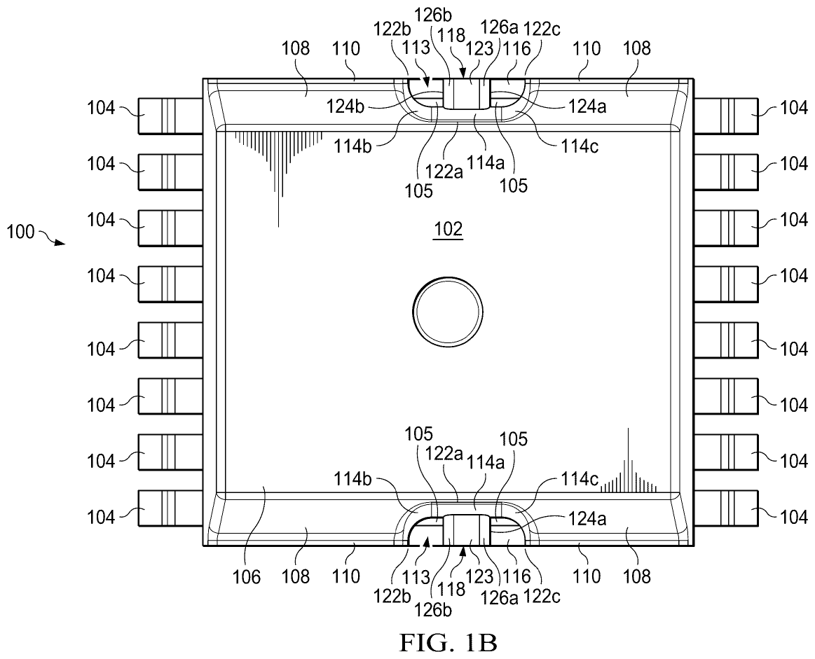

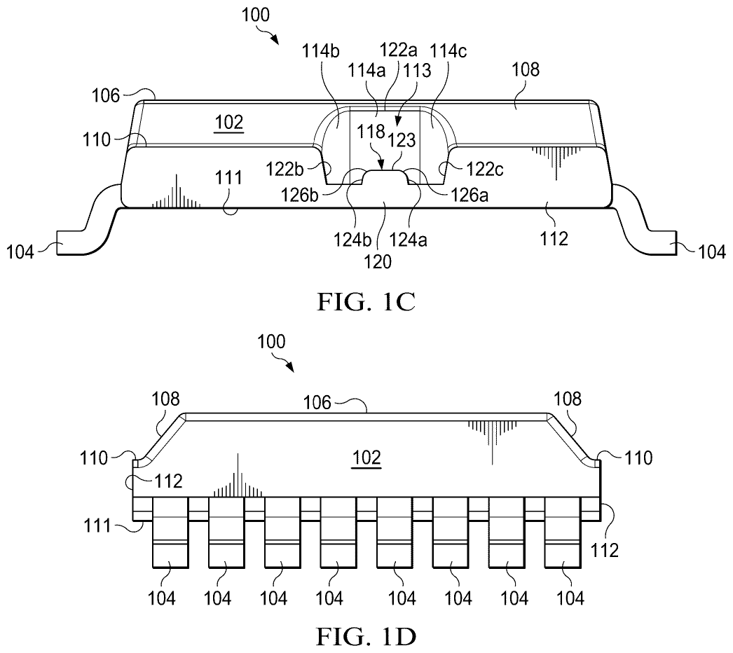

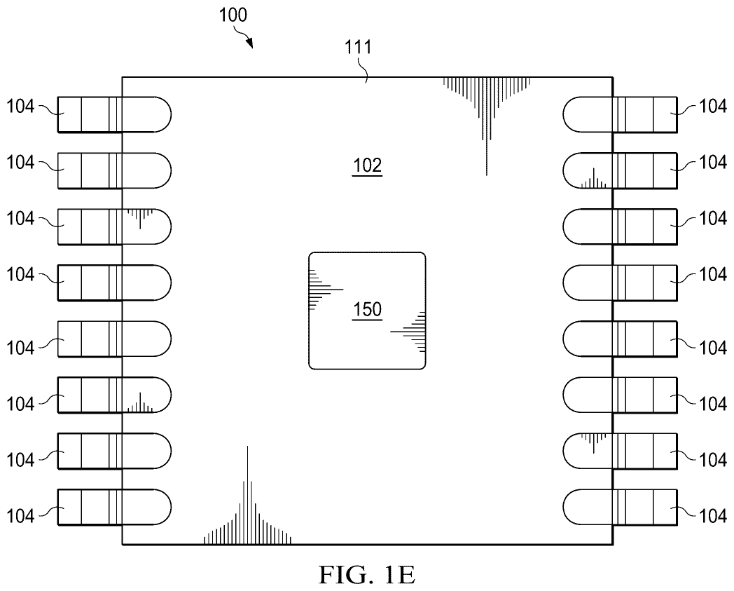

FIGS. 1A-1E are perspective, top-down, profile, profile, and bottom-up views of a semiconductor package 100 manufactured according to the mold compound void mitigation process described herein. The mold compound void mitigation process entails the use of a particular mold chase tooling that mitigates the formation of mold compound voids. Examples of the mold chase tooling are described further below. The mold chase tooling results in specific physical features on the semiconductor package 100 that are now described. The semiconductor package 100 may include a mold compound 102 and conductive terminals 104 (e.g., leads, such as gullwing style leads, although other types of conductive terminals that provide electrical contacts on an exterior surface of the semiconductor package 100 are also contemplated and included in the scope of this disclosure). The conductive terminals 104 may be connected to, or may be part of, other metal components that are covered by the mold compound 102. Generally, the term “metal components” refers to any metal component(s) that are part of the semiconductor package 100 and that were previously part of a lead frame or lead frame strip used to manufacture the semiconductor package 100. Examples of metal components include tie bars, dam bars, support frames, die pads, lateral members, conductive terminals (e.g., leads), etc.

The mold compound 102 may include a top surface 106, a top surface 110, and a sloped surface 108 extending between the top surfaces 106, 110. In examples, the top surface 106 is the top-most surface of the semiconductor package 100 and of the mold compound 102. The mold compound 102 may include a bottom surface 111 and a lateral surface 112. The lateral surface 112 may extend from the top surface 110 to the bottom surface 111.

During manufacture, and specifically, during the application of the mold compound 102, the mold chase tooling causes the formation of a cavity 113. Details regarding the formation of the cavity 113 are provided further below. In examples, the cavity 113 opens to the sloped surface 108, to the top surface 110, and to the lateral surface 112. In examples, the cavity 113 may include a back wall 114a and lateral walls 114b and 114c, which may collectively be referred to herein as the wall 114. The wall 114 may have a variable height. For example, the back wall 114a may have a greater height than the lateral walls 114b and 114c. In examples, the height of the wall 114 may gradually decline from the back wall 114a to the lateral wall 114b and from the back wall 114a to the lateral wall 114c. The back wall 114 may include curved and non-curved segments. The back wall 114a terminates at an edge 122a. The edge 122a is coincident with the sloped surface 108. The lateral walls 114b and 114c terminate at edges 122b and 122c, respectively. The edges 122b and 122c are coincident with the lateral surface 112. The edge 122a may extend from the edge 122b to the edge 122c.

The cavity 113 may include a floor 116. The floor 116 may have multiple segments. The segments of the floor 116 may be contiguous or non-contiguous. In the example of FIG. 1A, the floor 116 is non-contiguous and has two separate segments separated by an elevated member 118, described below. Metal component(s), such as lateral bars 105, are exposed on the floor 116, as shown. In examples, the top surfaces of the metal component(s) that are exposed on the floor 116 are approximately flush with the floor 116. In examples, the metal component(s) may be exposed on an area of the floor 116 that intersects with the wall 114. For example, the metal component(s) may be exposed on an area of the floor 116 that intersects with the back wall 114a. When the floor 116 includes multiple, non-contiguous segments, as in FIG. 1A, the metal component(s) exposed on the different floor segments may be a single metal component or multiple metal components.

In examples, the cavity 113 includes the elevated member 118 on the floor 116. The elevated member 118 may be centered on the floor 116. The elevated member 118 may extend from the lateral surface 112 toward a center of the semiconductor package 100. The elevated member 118 may have a surface 120 that is approximately flush with the lateral surface 112, and the opposite end of the elevated member 118 from the surface 120 may contact the back wall 114a. The elevated member 118 may have any suitable shape, but in at least some examples, the elevated member 118 may include a top surface 123, lateral surfaces 124a and 124b, and curved segments 126a and 126b. The curved segment 126a may extend between the top surface 123 and the lateral surface 124a, and the curved segment 126b may extend between the top surface 123 and the lateral surface 124b. The curvature of the curved segments 126a, 126b indicates that the tooling used to form the elevated member 118 lacks sharp (e.g., 90 degree) corners, as curved surfaces facilitate mold compound flow, and sharp corners can impede mold compound flow. More generally, any surfaces depicted in FIGS. 1A-1E as being curved or rounded may have such shapes due to the curvature of the corresponding tooling used to form those features, and such curvatures in the tooling may be employed to facilitate, rather than impede, mold compound flow.

Each of the lateral surfaces 124a, 124b and each of the curved segments 126a, 126b may extend from the surface 120 to the back wall 114a. The non-contiguous segments of the floor 116 may be positioned on either side of the elevated member 118. The portions of the metal component(s) (e.g., lateral bars 105) that are exposed on the floor 116 may also be positioned on either side of the elevated member 118. The elevated member 118 has a thickness, as measured from the floor 116 to the top surface 123, ranging from 200 microns to 300 microns, with a thickness below this range being disadvantageous because it indicates the usage of mold chase tooling that was inadequately sized to facilitate proper mold compound flow and thus is likely to produce mold compound voids, and with a thickness above this range being disadvantageous because it indicates the usage of mold chase tooling that was oversized, resulting in an inappropriately large mold compound thickness that adds weight, increases manufacturing cost, reduces blade saw longevity, increases manufacturing time, etc. The elevated member 118 has a width, as measured by the distance between the lateral surfaces 124a and 124b, that ranges from 300 microns to 400 microns, with a width less than this range being disadvantageous because it is inadequately sized to facilitate proper mold compound flow and thus is likely to produce mold compound voids, and with a width above this range being disadvantageous because it results in an inappropriately large mold compound thickness that adds weight, increases manufacturing cost, reduces blade saw longevity, increases manufacturing time, etc.

The bottom-up view of FIG. 1E depicts a bottom surface of a die pad 150. The die pad 150 is coupled to a semiconductor die within the semiconductor package 100 and is described in greater detail below.

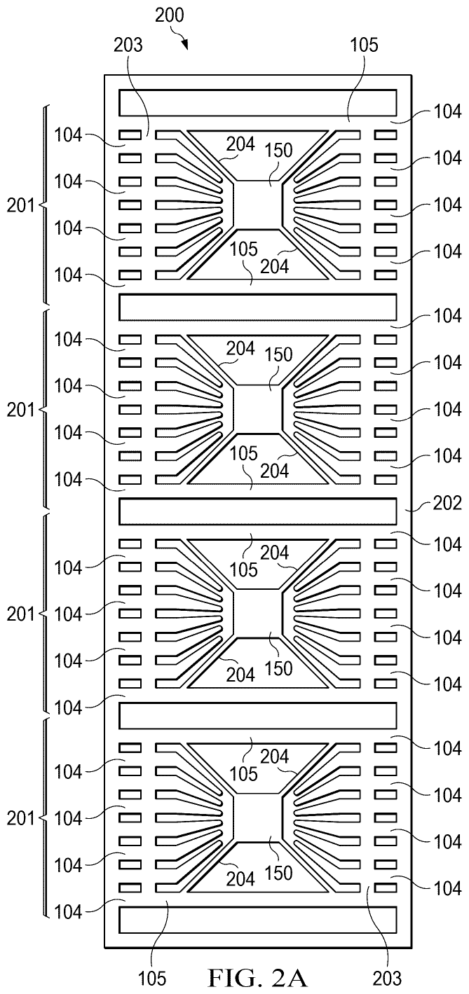

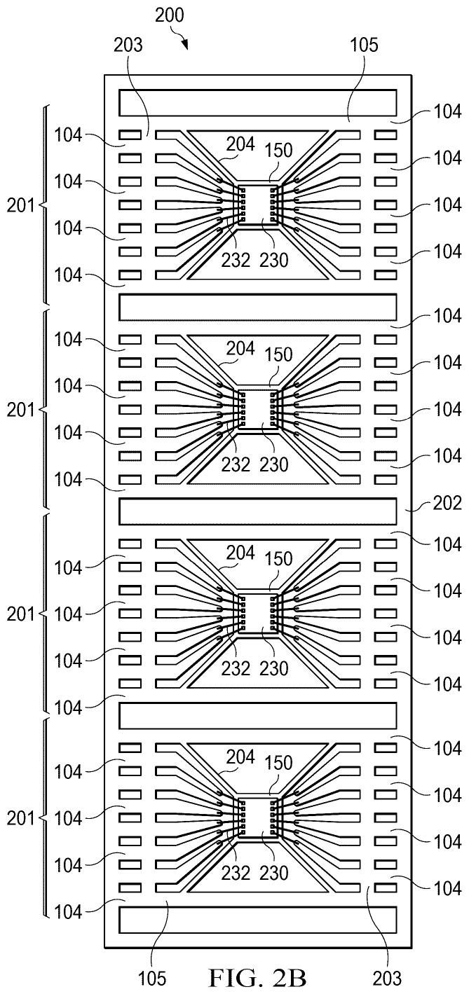

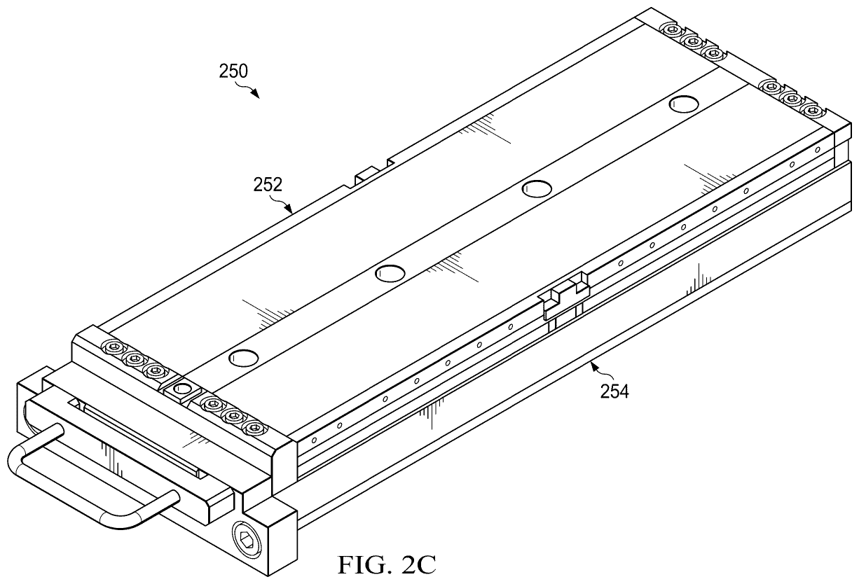

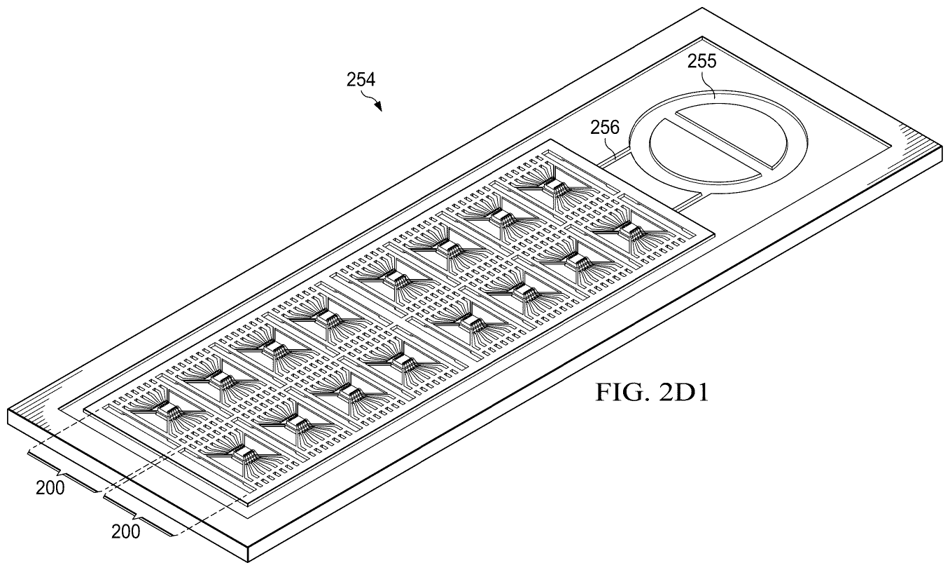

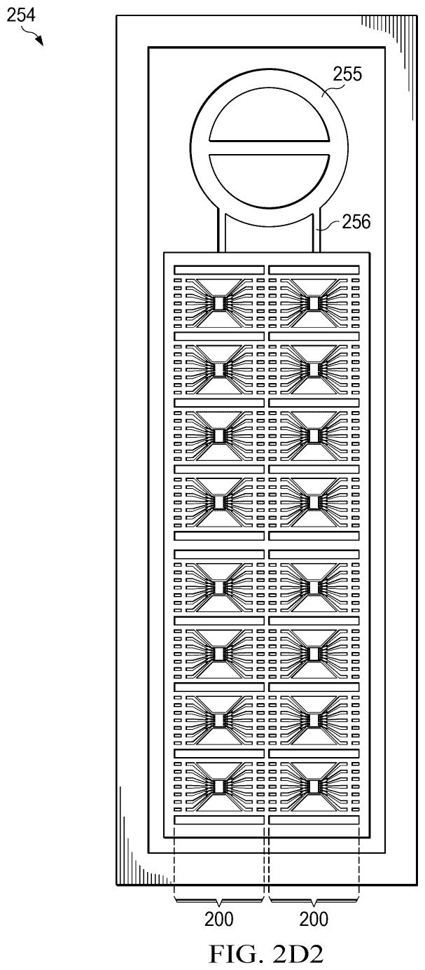

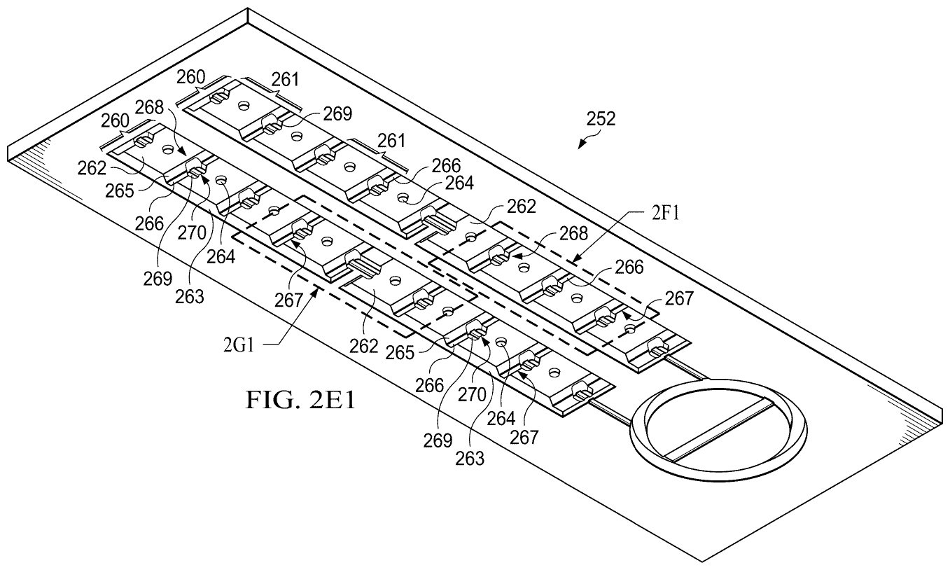

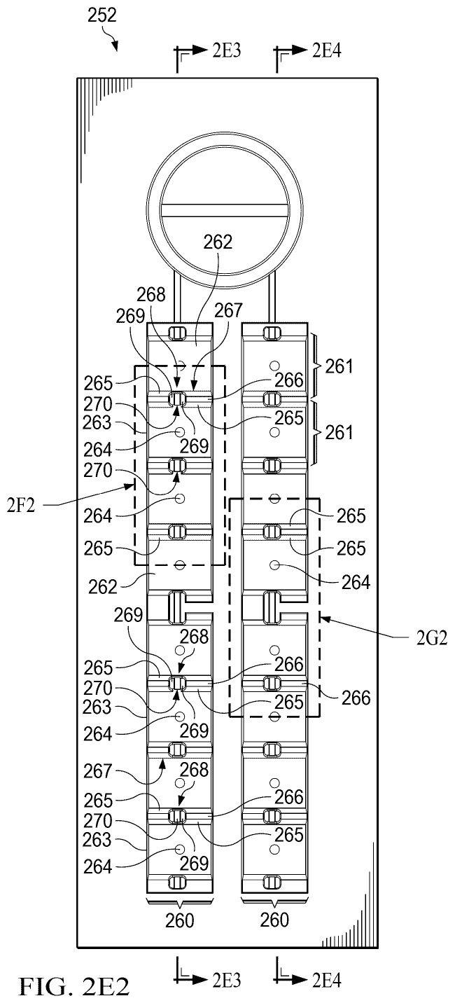

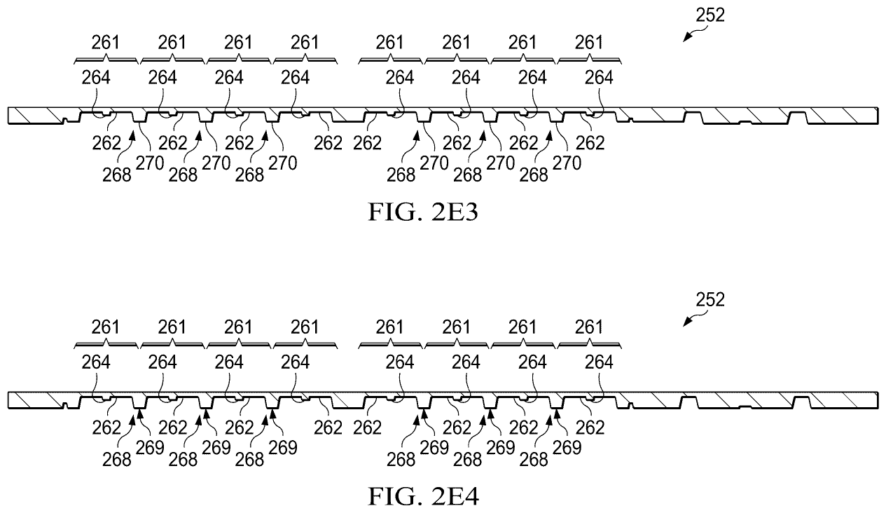

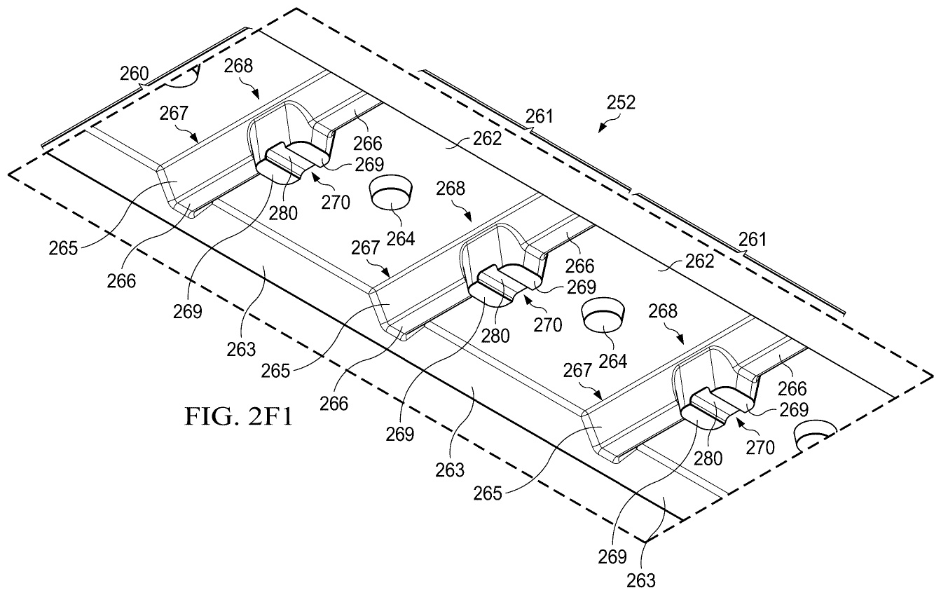

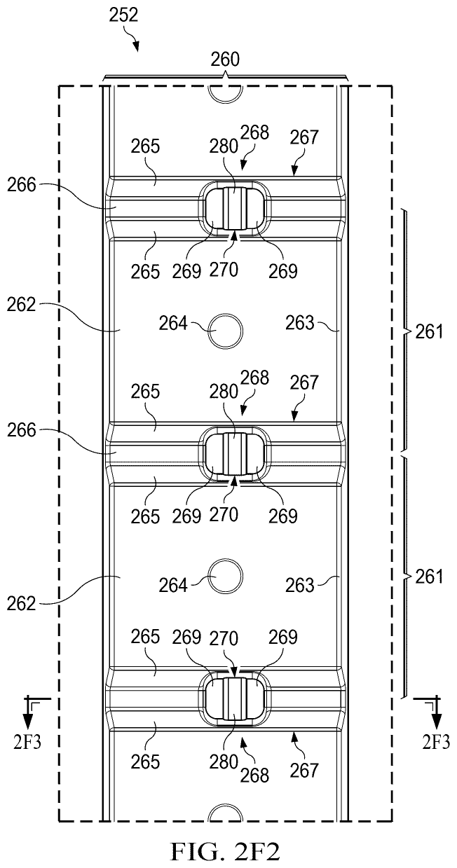

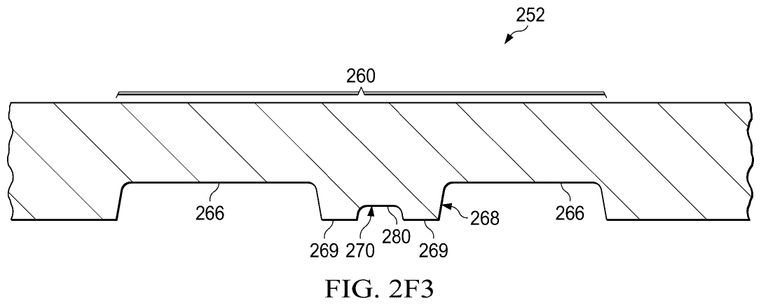

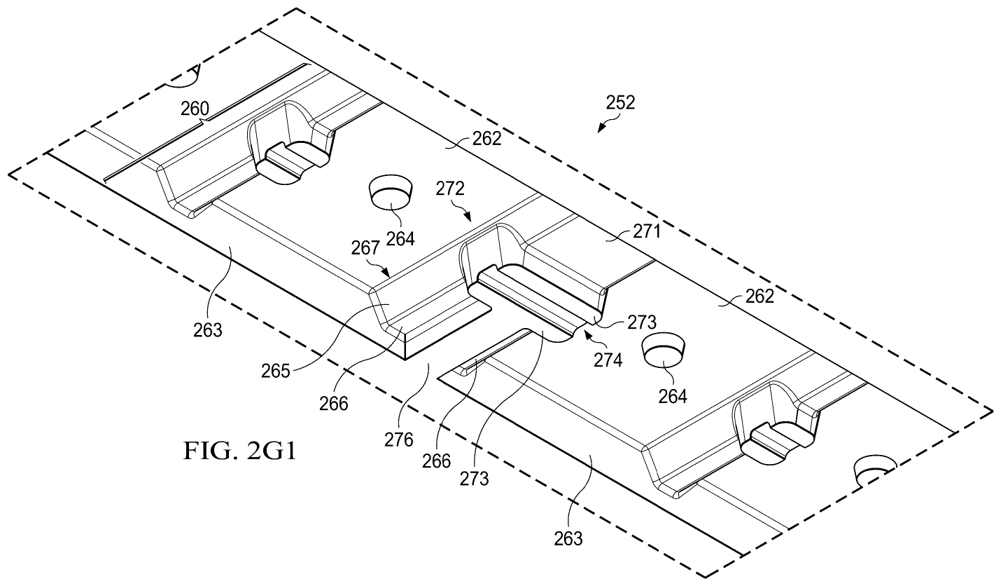

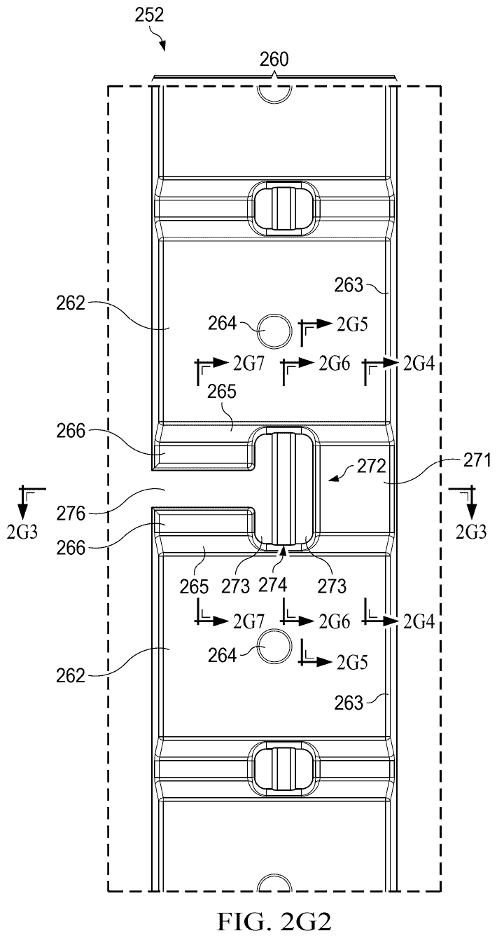

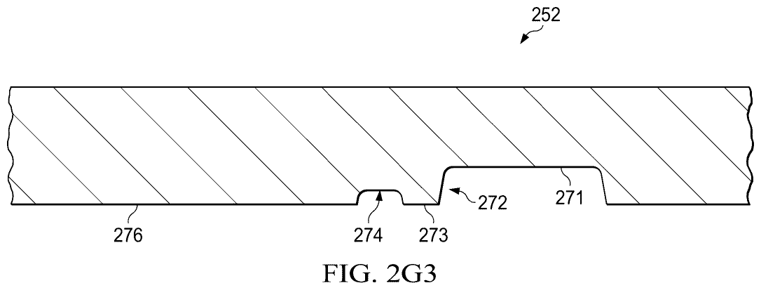

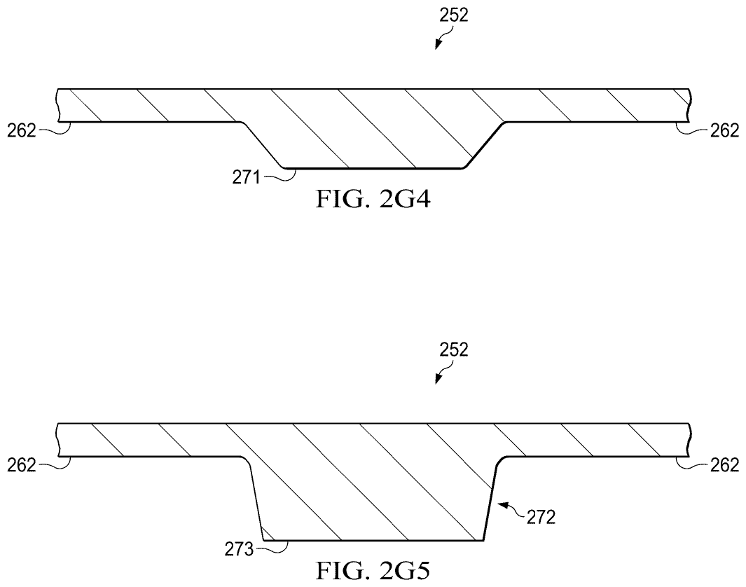

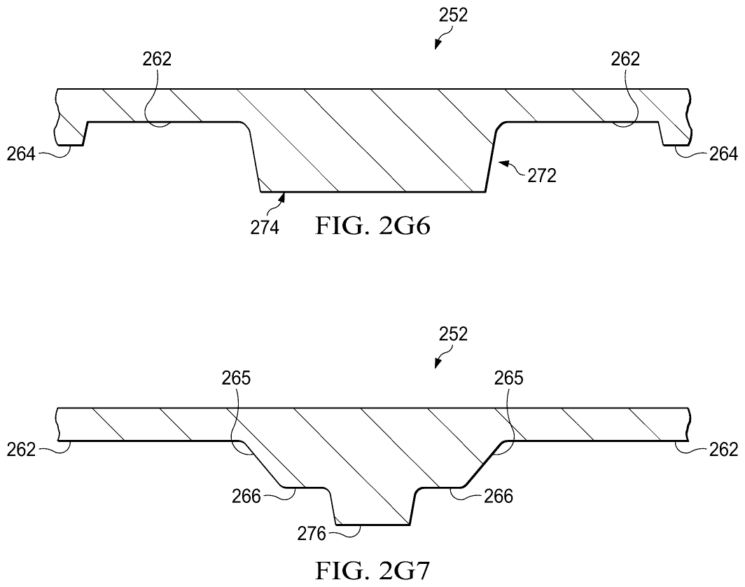

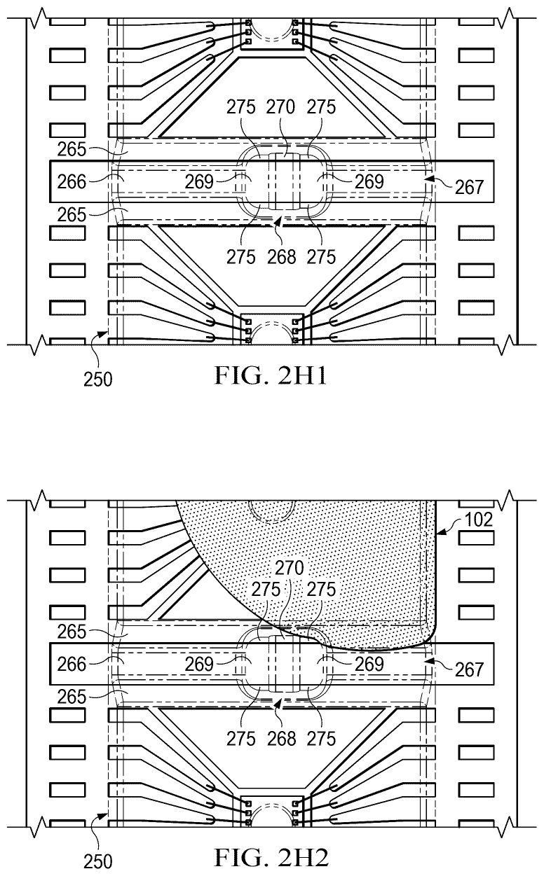

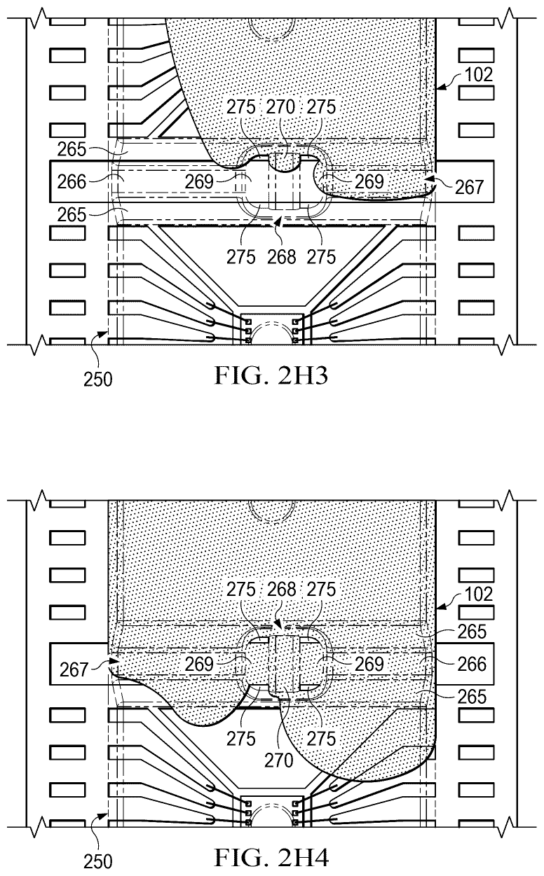

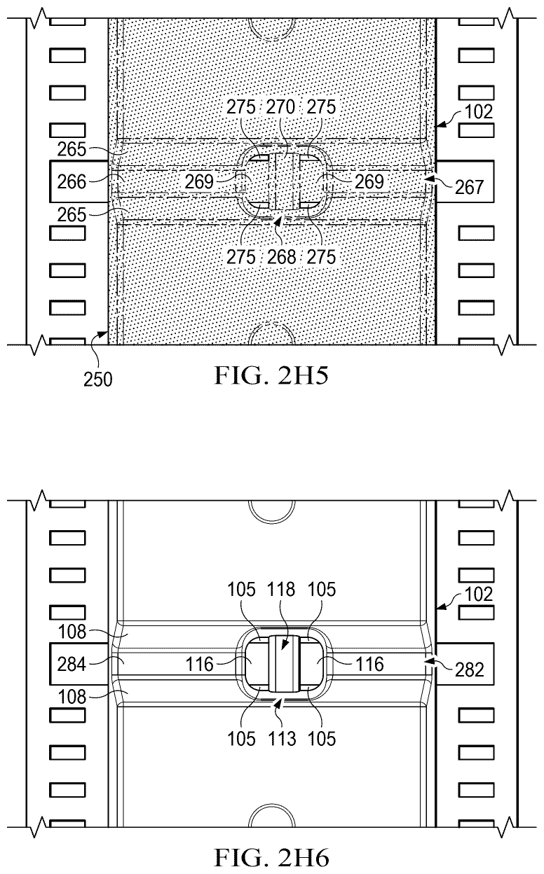

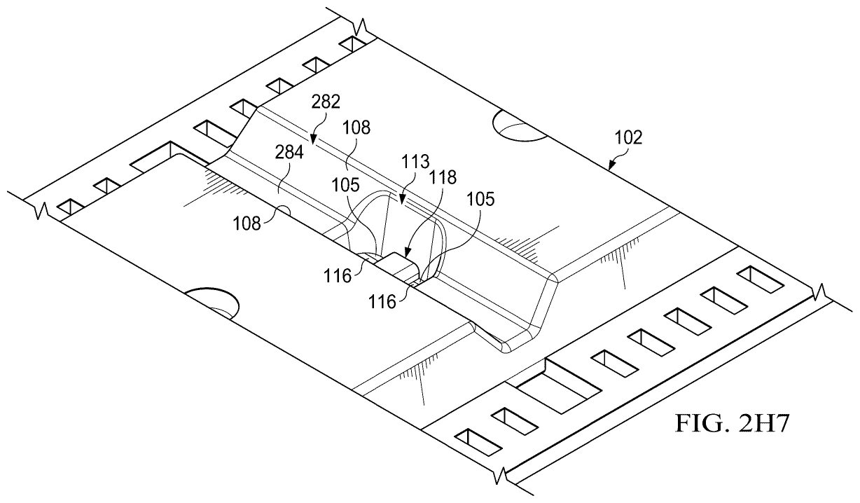

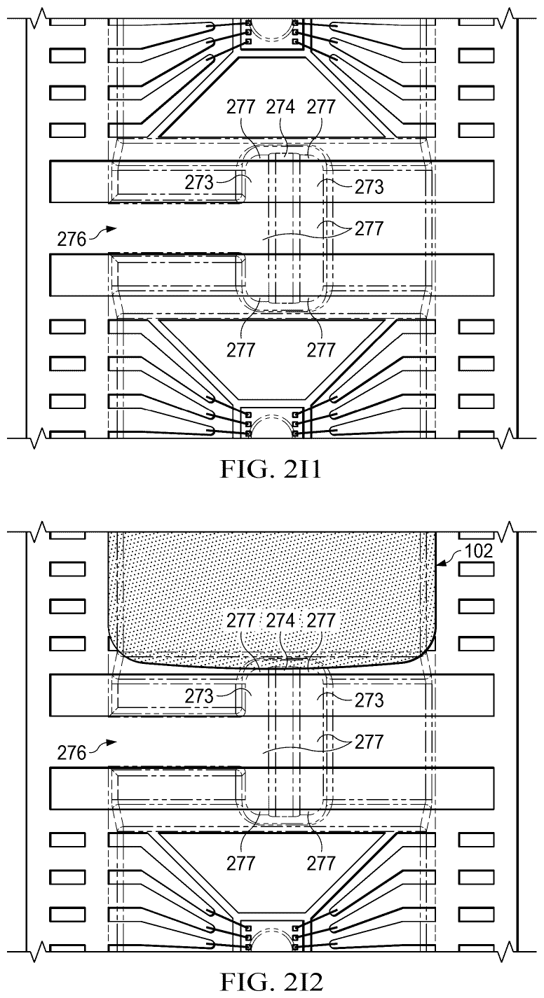

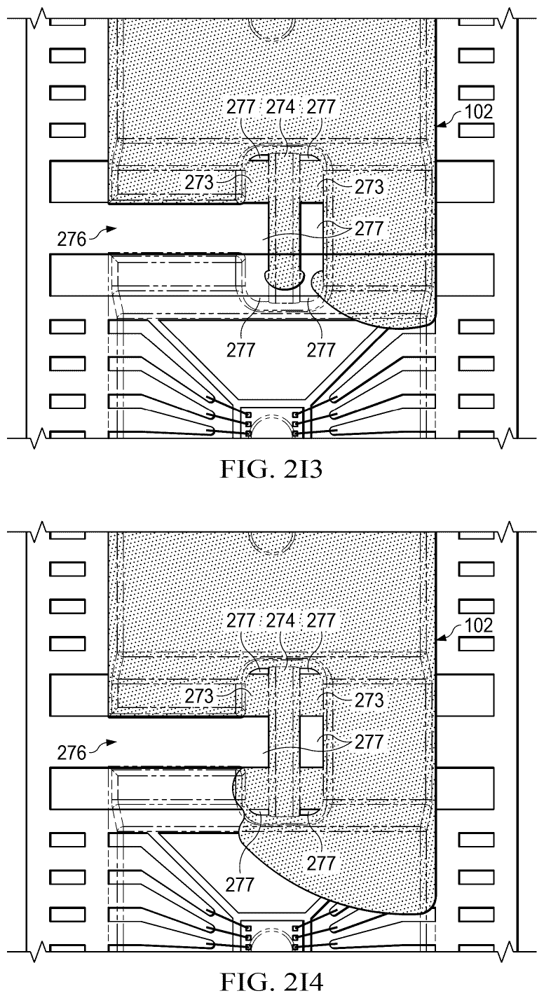

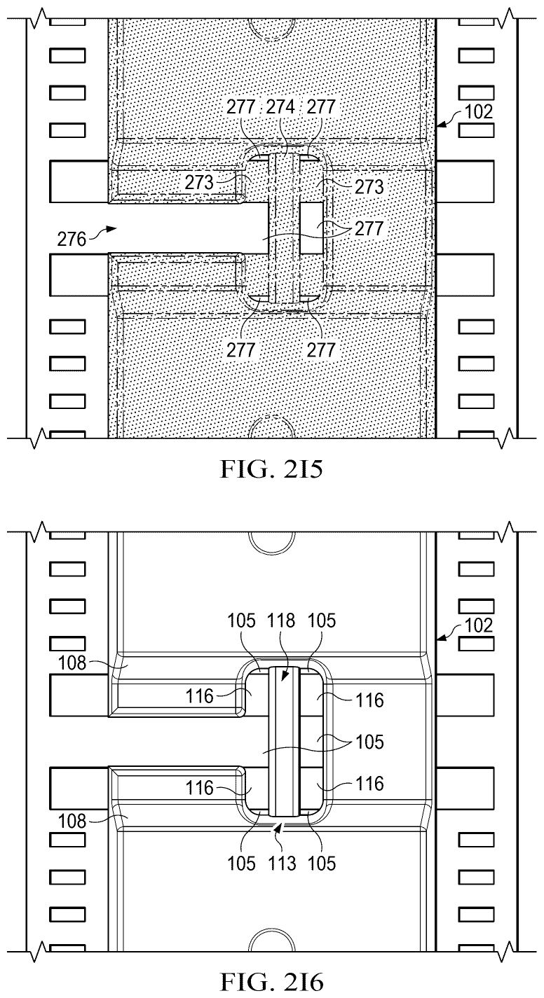

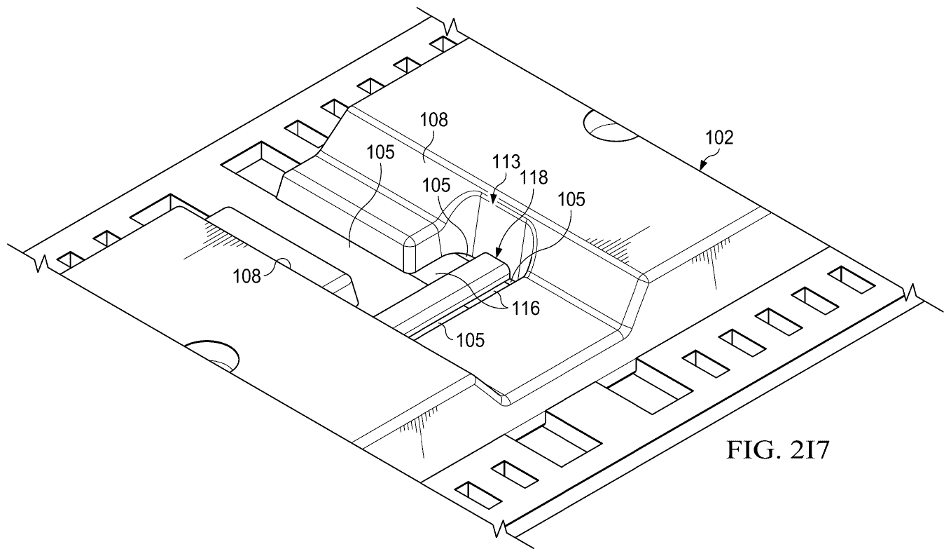

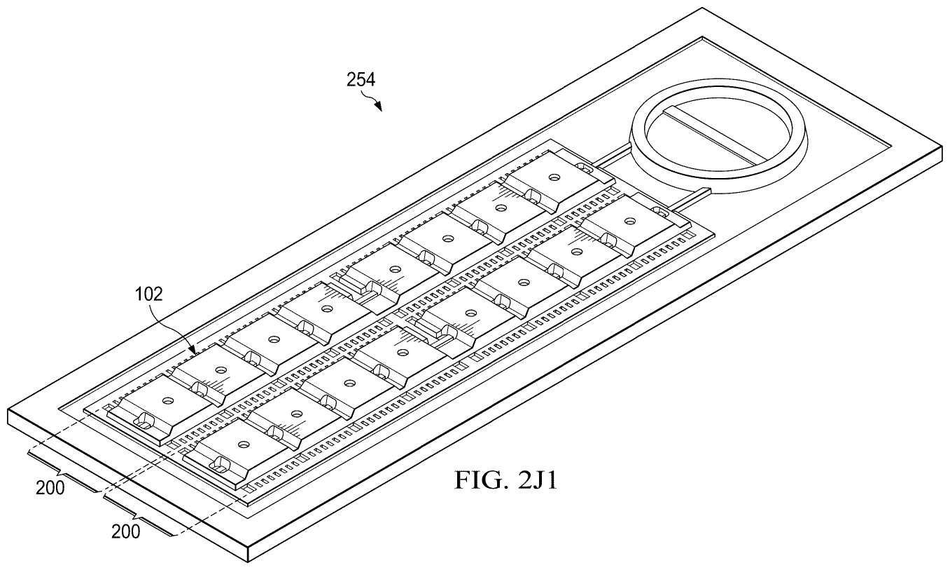

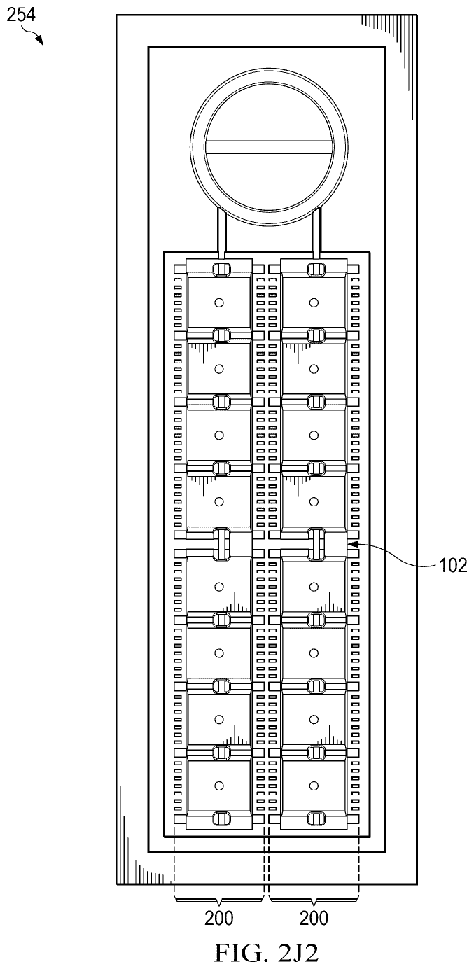

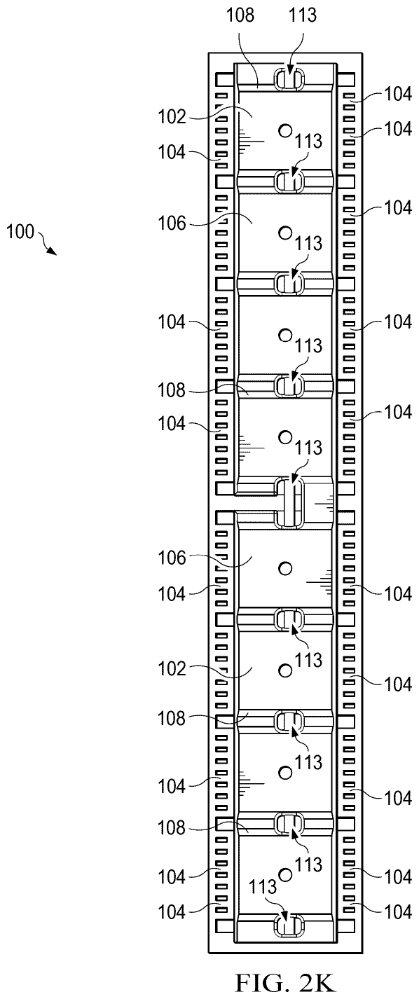

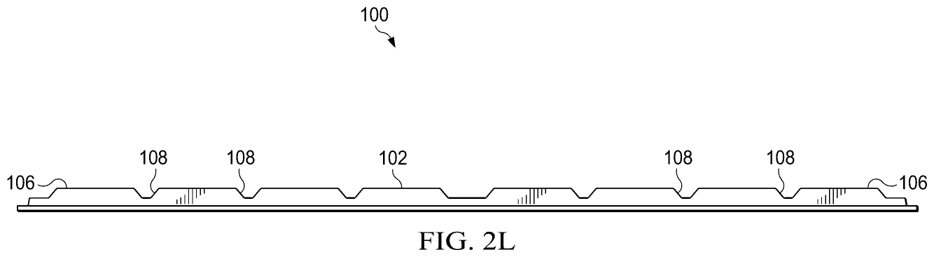

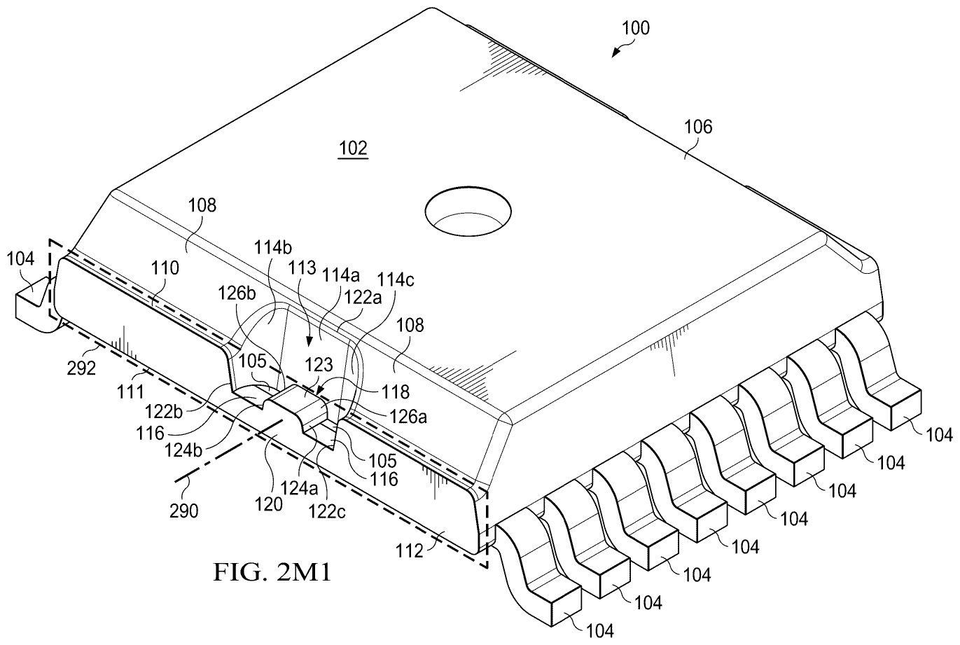

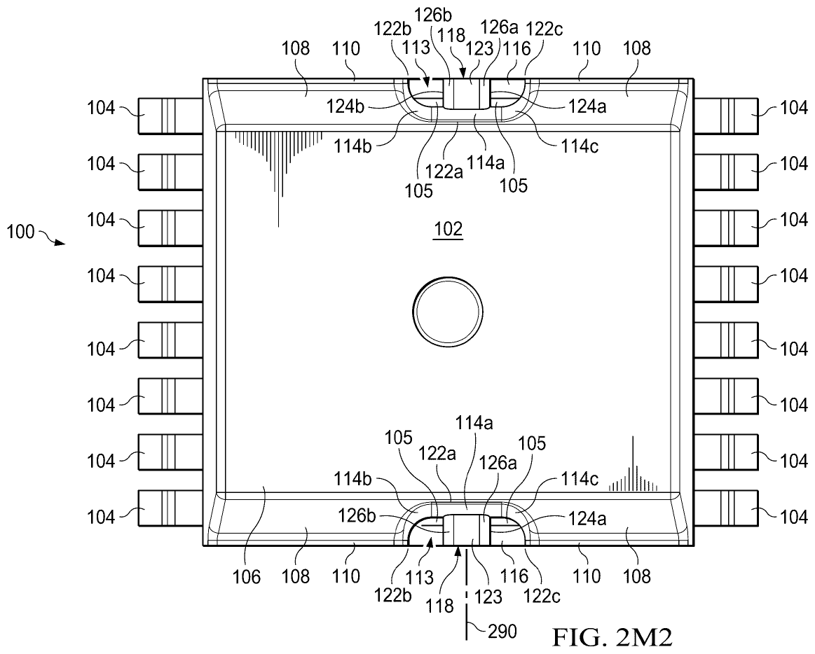

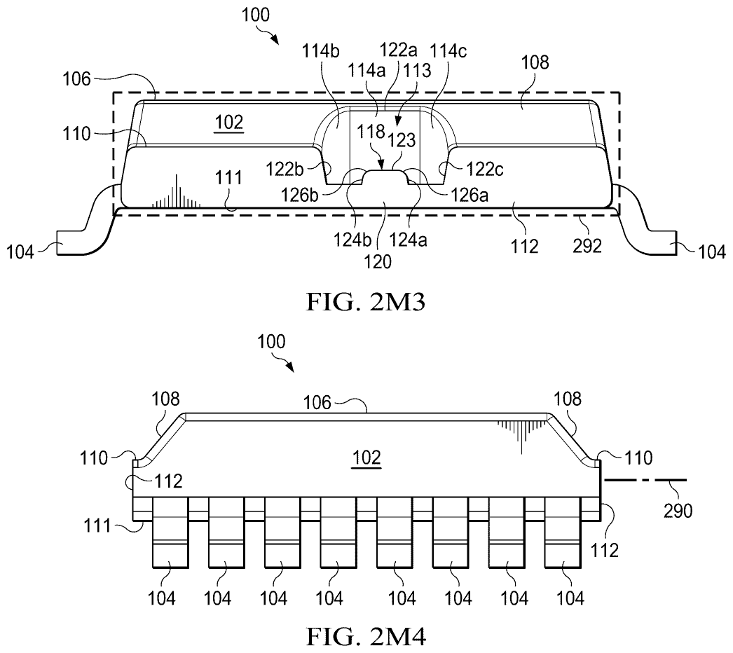

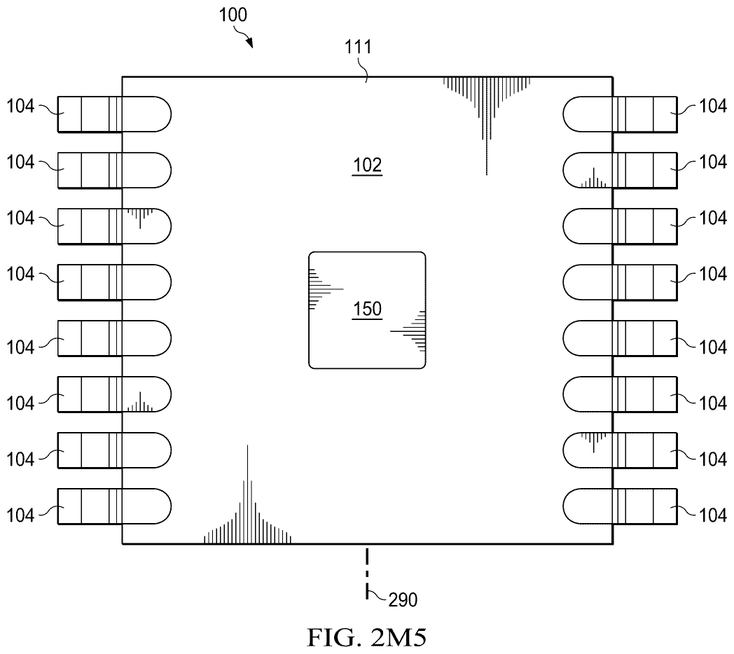

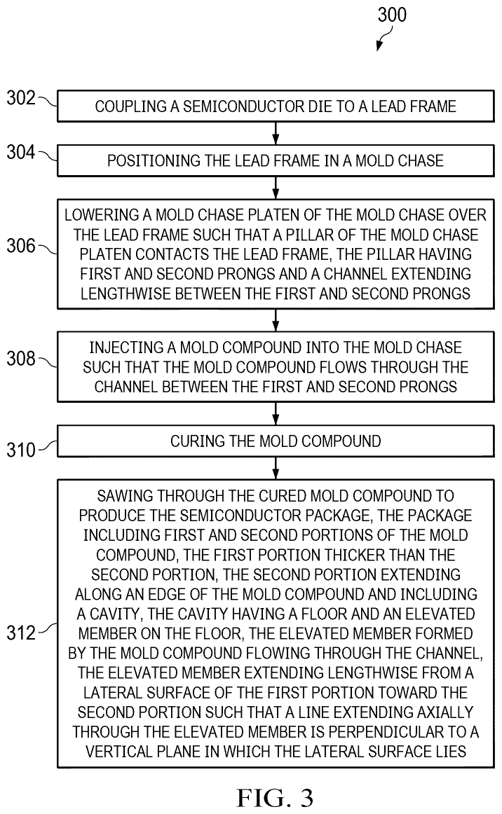

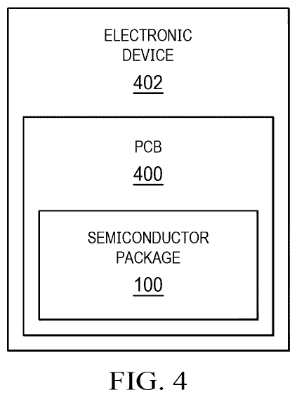

FIGS. 2A-2M5 are a process flow of a semiconductor package manufacturing process that mitigates the formation of mold compound voids, in accordance with various examples. FIG. 3 is a flow diagram of a semiconductor package manufacturing method 300 that mitigates the formation of mold compound voids, in accordance with various examples. Accordingly, FIGS. 2A-2M5 and FIG. 3 are now described in parallel.

The method 300 may include coupling a semiconductor die to a lead frame (302). FIG. 2A is a top-down view of a lead frame strip 200 including multiple lead frames 201. A lead frame 201 may include a die pad 150 and various metal components, such as conductive terminals 104, support frames 202, dam bars 203, tie bars 204, and lateral bars 105. The die pad 150 is configured to support a semiconductor die that may be coupled to the die pad 150 by a suitable die attach material. The conductive terminals 104 provide electrical pathways by which signals may be exchanged between a semiconductor die on the die pad 150 and other electrical components and devices. The support frames 202 facilitate physical manipulation and placement of the lead frame strip 200 during manufacturing processes. The dam bars 203 restrict mold compound flow during manufacturing processes. The tie bars 204 provide physical support to the die pad 150 and may provide physical support to other components of the lead frames 201 as well. The specific geometry of the lead frames 201 shown in FIG. 2A is illustrative. Lead frame 201 geometries may be application-specific, and any and all such geometries are contemplated and included in the scope of this disclosure.

FIG. 2B is a top-down view of the lead frame strip 200 of FIG. 2A, except that semiconductor dies 230 are coupled to the die pads 150 (e.g., using a suitable die attach material). The semiconductor dies 230 may be coupled to the conductive terminals 104 by bond wires 232. In some examples, the semiconductor dies 230 may be coupled to the conductive terminals 104 and the die pad 150 may be omitted. In such examples, which may be referred to as “flip chip” configurations, the device side of each semiconductor die 230 on and/or in which circuitry is formed is oriented downward, facing the conductive terminals 104, and is coupled to one or more of the conductive terminals 104 by solder bumps.

The method 300 may include positioning the lead frame in a mold chase (304). FIG. 2C is a perspective, exterior view of an example mold chase 250. The example mold chase 250 may include an upper mold chase platen 252 and a lower mold chase platen 254. In an example operation, the upper mold chase platen 252 is raised, lead frames 201 (e.g., in the form of lead frame strips 200) are positioned on the lower mold chase platen 254, and the upper mold chase platen 252 is lowered to the lower mold chase platen 254. As described below, the upper mold chase platen 252 includes pillars that contact the lead frames 201 and that mitigate the formation of mold compound voids when mold compound is injected into the mold chase 250 after closure of the upper mold chase platen 252.

FIG. 2D1 is a perspective view of a portion of the lower mold chase platen 254 in accordance with various examples, and FIG. 2D2 is a top-down view of a portion of the lower mold chase platen 254 in accordance with various examples. The lower mold chase platen 254 includes mold compound receptacles 255 (which may include, or be adapted to couple to, a sprue bushing), and mold compound channels 256 in fluid communication with the mold compound receptacles 255.

FIG. 2E1 is a perspective view of an underside of the upper mold chase platen 252, in accordance with various examples. FIG. 2E2 is a bottom-up view of the underside of the upper mold chase platen 252. FIGS. 2E3 and 2E4 are cross-sectional views of the upper mold chase platen 252, in accordance with various examples. The upper mold chase platen 252 includes multiple elongated cavities 260. Each of the cavities 260 may include multiple units 261. Each of the units 261 may include a floor 262, walls 263 immediately adjacent to the floor 262, a vertical member 264 extending away from the floor 262, and sloped surfaces 265. Each of the sloped surfaces 265 includes a first edge that contacts the floor 262 and a second edge that contacts a flat surface 266. Together, a flat surface 266 and the two sloped surfaces 265 that contact that flat surface 266 may be referred to herein as a protrusion 267. In examples, each instance of the floor 262 is flanked by multiple (e.g., two) protrusions 267.

Pillars 268 may be positioned on each of the protrusions 267. Each of the pillars 268 may include prongs 269 and a channel 270 extending between the prongs 269. In examples, each pillar 268 include two prongs 269, although any number of prongs may be included in each pillar 268. In examples, the horizontal cross-section of each prong 269 may be semi-circular or semi-ovoid, which facilitates mold compound flow as opposed to at least some other shapes, but the scope of this disclosure is not limited to any particular shape. For example, the horizontal cross-sectional of each prong 269 may be triangular. Regardless of the particular shape used, it is critical that the shape selected facilitate mold compound flow, rather than impede mold compound flow.

In examples, the channel 270 has a bottom-most surface (e.g., a floor) that is coincident with the flat surface 266. In other examples, the bottom-most surface of the channel 270 is elevated relative to the flat surface 266, meaning that the bottom-most surface of the channel 270 is farther from the floor 262 than is the flat surface 266. The height of the channel 270, as measured from the bottom-most surface of the channel 270 to distal ends of the prongs 269, ranges from 200 microns to 300 microns, with a height below this range being disadvantageous because it is inadequately sized to facilitate proper mold compound flow and thus is likely to produce mold compound voids, and with a height above this range being disadvantageous because it results in an inappropriately large mold compound thickness that adds weight, increases manufacturing cost, reduces blade saw longevity, increases manufacturing time, etc. The height of the channel 270 is less than the heights of the prongs 269 and the height of the pillar 268. The width of the channel 270, as measured by the distance between the prongs 269, ranges from 650 microns to 850 microns, with a width below this range being disadvantageous because it is inadequately sized to facilitate proper mold compound flow and thus is likely to produce mold compound voids, and with a width above this range being disadvantageous because it results in an inappropriately large mold compound thickness that adds weight, increases manufacturing cost, reduces blade saw longevity, increases manufacturing time, etc.

FIGS. 2F1, 2F2, and 2F3 are detailed perspective, top-down, and cross-sectional views, respectively, of the protrusion 267, the prongs 269, and the channel 270 between the prongs 269. As shown, the height of the floor 280 of the channel 270 may be greater than the height of the flat surface 266. The heights of the prongs 269 may be greater than the height of the floor 280. In examples, the heights of the prongs 269 are approximately equal.

FIGS. 2G1-2G7 are perspective, bottom-up, and various cross-sectional views of another example cavity 260 in the upper mold chase platen 252. The example cavity 260 may include the floor 262, the walls 263 circumscribing the floor 262, the vertical member 264, the sloped surfaces 265, and the flat surfaces 266. Further, the example cavity 260 may include a pillar 272. The example pillar 272 may include prongs 273 and a channel 274 extending between the prongs 273. A flat segment 271 extends along a length of the prongs 273. A flat segment 276 extends laterally from the pillar 272 to one of the walls 263. As shown, the top surface of the flat segment 271 may have an edge that is coincident with a bottom edge of the closest prong 273. In contrast, the top surface of the flat segment 276 may have an edge that is coincident with the top edge of the closest prong 273.

The method 300 may include lowering a mold chase platen of the mold chase over the lead frame such that a pillar of the mold chase platen contacts the lead frame (306). The pillar has first and second prongs and a channel extending lengthwise between the first and second prongs (306). For example, the upper mold chase platen 252 (e.g., FIG. 2E1, 2F1) may be lowered onto the lower mold chase platen 254 (e.g., FIG. 2D1). Consequently, some portions of the upper mold chase platen 252 may establish contact with the lead frame strips 200 that are seated in the lower mold chase platen 254, and/or may establish contact with portions of the lower mold chase platen 254. For example, the walls 253 of the upper mold chase platen 252 may contact the top surface of the lower mold chase platen 254, such that when mold compound is subsequently injected into the mold chase 250, mold compound does not escape the cavities 260. Further, the pillars 268 and 272 (e.g., FIGS. 2E1, 2F1, 2G1) may establish contact with portions of the lead frame strips 200, such as the lateral bars 105 (e.g., FIG. 2A). For example, one end of a prong 269 or 273 may contact a lateral bar 105 of a first lead frame 201, and a second, opposing end of that prong 269 or 273 may contact a lateral bar 105 of a second lead frame 201 that is positioned consecutively adjacent to the first lead frame 201.

The method 300 may include injecting a mold compound into the mold chase such that the mold compound flows through the channel between the first and second prongs (308) and curing the mold compound (310). FIG. 2H1 is a top-down, see-through view of the upper mold chase platen 252 and the lower mold chase platen 254 in contact with each other. A lead frame strip 200 is positioned between the upper and lower mold chase platens 252, 254, but the lead frame strip 200 is not fully depicted in FIG. 2H1 to reduce clutter and facilitate ease of understanding. Each protrusion 267, which includes two sloped surfaces 265 and a flat surface 266 between the sloped surfaces 265, is positioned between consecutively adjacent lead frames 200. Consequently, the two prongs 269 of the pillar 268 contact the two lateral bars 105 at four contact points 275. The channel 270 is between the prongs 269, as shown.

Mold compound 102 may be injected via the mold compound receptacles 255 (FIG. 2D1), and the mold compound 102 may flow through the mold compound channels 256 (FIG. 2D1) and onto the lead frame strips 200 (FIG. 2D1). FIGS. 2H2-2H5 depict an example flow of the mold compound 102, and specifically, toward and through the structure of FIG. 2H1. In particular, FIG. 2H2 depicts the initial flow of the mold compound 102 toward the protrusion 267 and the pillar 268. FIG. 2H3 depicts the mold compound 102 flowing through the channel 270 and around the prongs 269. The mold compound 102 may flow below the prongs 269, on lateral sides of the prongs 269, and through the channel 270, thereby resulting in the mold compound flow pattern depicted in FIGS. 2H3-2H5. No mold compound 102 covers the contact points 275, because the prongs 269 contact the lateral bars 105 at the contact points 275, prohibiting mold compound flow therebetween. Similarly, the mold compound 102 flows in areas not blocked by the protrusion 267, resulting in the mold compound flow pattern depicted in FIGS. 2H2-2H5. The mold compound 102 is cured.

FIGS. 2H6 and 2H7 are top-down and perspective views, respectively, of a portion of the molded and cured lead frame strip 200. The structure depicted in FIG. 2H6 is identical to that shown in FIG. 1A, except that consecutively adjacent lead frames 201 have not yet been singulated to produce the structure of FIG. 1A. Thus, the top surfaces 110 and lateral surfaces 112 of consecutively adjacent lead frames 201 are joined to each other in this pre-singulation state.

Conventional pillar clamps used to mechanically stabilize lead frame strips seated in lower mold chase platens cause mold compound void formation due to the impact the pillar clamps have on the fluid dynamics of the mold compound. As the mold compound flows around the pillar clamps, voids are formed, especially at locations where different mold compound flows meet. In contrast, the pillar 268, including the prongs 269 and the channel 270, result in the mold flow dynamics depicted in FIGS. 2H1-2H7, which mitigates void formation. In particular, the presence of the channel 270 results in central mold compound flow through the pillar 268, and this central mold compound flow joins with the mold compound flows around the two prongs 269, mitigating the formation of voids that would otherwise form at or near that location. Further, the protrusion 267 (e.g., FIG. 2E1) causes the mold compound 102 to form a valley 282. Singulation is subsequently performed on a floor 284 of the valley 282, which is thinner than other portions of the mold compound 102. Consequently, saw blade life is preserved, manufacturing speed is increased relative to packages with substantially uniform mold compound thickness, and manufacturing costs are reduced. In addition, the use of less mold compound 102 results in reduced semiconductor package bulk, size, and weight.

The mold compound flow patterns relative to the pillars 272 (FIG. 2G1) may differ from those relative to the pillars 268 (FIG. 2E1). For example, FIG. 2I1 is a top-down, see-through view of the upper mold chase platen 252 and the lower mold chase platen 254 in contact with each other. A lead frame strip 200 is positioned between the upper and lower mold chase platen 252, 254, but the lead frame strip 200 is not fully depicted in FIG. 2I1 to reduce clutter and facilitate ease of understanding. The prongs 273 may contact metal components of the lead frame strip 200, such as lateral bars 105, at contact points 277. FIGS. 2I1-2I5 depict flow of the mold compound 102 upon injection. In FIG. 2I2, the mold compound 102 approaches the prongs 273 and the channel 274 between the prongs 273. In FIG. 2I3, the mold compound 102 flows through the channel 274, around the prongs 273, and around the flat segment 276. Consequently, the mold compound 102 covers the areas other than the contact points 277. The mold compound 102 is cured.

FIGS. 2I6 and 2I7 are top-down and perspective views, respectively, of a portion of the molded and cured lead frame strip 200. The structure depicted in FIG. 2I6 is identical to that shown in FIG. 1A, except that consecutively adjacent lead frames 201 have not yet been singulated to produce the structure of FIG. 1A. The various technical advantages described above relative to the mold compound flow dynamics depicted in FIGS. 2H1-2H7 also apply to the mold compound flow dynamics depicted in FIGS. 2I1-2I7.

FIGS. 2J1 and 2J2 are perspective and top-down views of portions of the lower mold chase platen 254 after the mold compound 102 is cured and the upper mold chase platen 252 is raised. The lead frame strips 200 are covered by the cured mold compound 102, as shown. FIG. 2K is a top-down, detailed view of a single lead frame strip 200 covered with the cured mold compound 102. FIG. 2L is a profile view of the lead frame strip 200 of FIG. 2K.

The method 300 may include sawing through the cured mold compound to produce the semiconductor package (312). The package may include first and second portions of the mold compound, with the first portion thicker than the second portion (312). The second portion may extend along an edge of the mold compound and include a cavity (312). The cavity may include a floor and an elevated member on the floor (312). The elevated member may be formed by the mold compound flowing through the channel (312). The elevated member may extend lengthwise from a lateral surface of the first portion toward the second portion such that a line extending axially through the elevated member is perpendicular to a vertical plane in which the lateral surface lies (312). Singulation of the molded and cured lead frame strips 200 (e.g., by a mechanical saw) may result in individual semiconductor packages 100, as shown in the various views of FIGS. 2M1-2M5. In FIGS. 2M1-2M5, the thickness of the mold compound 102 is greater at top surface 106 than at top surface 110. The cavity 113 includes the floor 116 and the elevated member 118. The elevated member 118 is formed by the flow of the mold compound 102 through the channels 270 and 274, as FIGS. 2H1-2H7 and 2I1-2I7 depict. The elevated member 118 extends lengthwise from the lateral surface 112 toward the thicker portion of the mold compound 102, such that a line 290 extending axially through the elevated member 118 is perpendicular to a vertical plane 292 in which the lateral surface 112 lies.

Post-singulation, the semiconductor package 100 may be coupled (e.g., soldered) to a printed circuit board (PCB) 400. The PCB 400, in turn, may be included as part of an electronic device 402. Examples of the electronic device 402 may include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die;
a conductive terminal coupled to the semiconductor die; and
a mold compound covering the semiconductor die and the conductive terminal, the mold compound including first and second portions, the first portion thicker than the second portion, the second portion extending along an edge of the mold compound and including a cavity, the cavity including a floor and an elevated member on the floor, the elevated member extending lengthwise from a lateral surface of the first portion toward the second portion such that a line extending axially through the elevated member intersects a plane in which the lateral surface lies.

2. The semiconductor package of claim 1, wherein the elevated member lies along a center of the floor.

3. The semiconductor package of claim 1, wherein the mold compound includes a sloped surface extending between a top surface of the first portion and a top surface of the second portion.

4. The semiconductor package of claim 3, wherein the cavity opens to the sloped surface.

5. The semiconductor package of claim 3, wherein the cavity opens to the top surface of the second portion.

6. The semiconductor package of claim 1, wherein a metal component of the semiconductor package is exposed on the floor of the cavity.

7. The semiconductor package of claim 6, wherein the metal component is exposed on the floor of the cavity on opposing sides of the elevated member.

8. The semiconductor package of claim 6, wherein the cavity includes a wall having opposing first and second ends, the first end of the wall coincident with a sloped surface, the sloped surface extending between top surfaces of the first and second portions, and the second end of the wall coincident with the metal component.

9. The semiconductor package of claim 8, wherein the wall is curved and has third and fourth opposing ends coincident with the lateral surface and with the floor of the cavity.

10. The semiconductor package of claim 8, wherein the elevated member has first and second opposing surfaces, the first surface of the elevated member coincident with the lateral surface, and the second surface of the elevated member contacting the wall.

11. The semiconductor package of claim 6, wherein the metal component is approximately flush with the floor of the cavity.

12. The semiconductor package of claim 1, wherein the elevated member has a thickness, as measured from the floor of the cavity to a topmost surface of the elevated member, between 200 microns and 300 microns.

13. The semiconductor package of claim 1, wherein the elevated member has multiple rounded edges.

14. A semiconductor package, comprising:
a semiconductor die;
a conductive terminal coupled to the semiconductor die; and
a mold compound covering the semiconductor die and the conductive terminal, the mold compound having a cavity that is open to multiple surfaces of the mold compound, the cavity having a floor and an elevated member extending along a center of the floor from a lateral surface of the mold compound toward a center of the semiconductor package, the cavity including a wall coincident with the multiple surfaces of the mold compound and with the floor, a metal component within the semiconductor package exposed to the cavity and forming part of the floor, an edge of the wall terminating at the metal component.

15. The semiconductor package of claim 14, wherein the mold compound includes first and second portions, the first portion thicker than the second portion, and wherein the second portion extends along an edge of the mold compound and is coincident with the cavity.

16. The semiconductor package of claim 15, wherein the mold compound includes a sloped surface extending between top surfaces of the first and second portions.

17. The semiconductor package of claim 16, wherein the cavity opens to the sloped surface and to the top surface of the second portion but not to the top surface of the first portion.

18. The semiconductor package of claim 14, wherein the wall has opposing ends that are coincident with the lateral surface.

19. The semiconductor package of claim 14, wherein the elevated member has a thickness, as measured from the floor of the cavity to a topmost surface of the elevated member, between 200 microns and 300 microns.

20. A method for manufacturing a semiconductor package, comprising:
coupling a semiconductor die to a lead frame;
positioning the lead frame in a mold chase;
lowering a mold chase platen of the mold chase over the lead frame such that a pillar of the mold chase platen contacts the lead frame, the pillar having first and second prongs and a channel extending lengthwise between the first and second prongs;
injecting a mold compound into the mold chase such that the mold compound flows through the channel between the first and second prongs;
curing the mold compound; and
sawing through the mold compound to produce the semiconductor package, the semiconductor package including first and second portions of the mold compound, the first portion thicker than the second portion, the second portion extending along an edge of the mold compound and including a cavity, the cavity having a floor and an elevated member on the floor, the elevated member formed by the mold compound flowing through the channel, the elevated member extending lengthwise from a lateral surface of the first portion toward the second portion such that a line extending axially through the elevated member is perpendicular to a vertical plane in which the lateral surface lies.

21. The method of claim 20, wherein the lead frame is exposed to the cavity and forms part of the floor.

22. The method of claim 21, wherein the contact between the pillar and the lead frame causes the lead frame to be exposed to the cavity by preventing the mold compound from covering the lead frame at a point of the contact.

23. The method of claim 20, wherein injecting the mold compound causes the mold compound to flow through the channel.

24. The method of claim 20, wherein the channel has a height that is less than a height of the pillar.

25. The method of claim 24, wherein the height of the channel is between 200 microns and 300 microns.

26. The method of claim 20, wherein the first prong has a first end and the second prong has a second end, and further comprising contacting the first end of the first prong and the second end of the second prong to a same segment of the lead frame.
